(19) United States
(12) Patent Application Publication
(10) Pub. No.: US 2026/0259282 A1
(43) Pub. Date: Sep. 3, 2026

(54) ARRANGEMENT AND METHOD

(71) Applicant: Schreiner Group GmbH & Co. KG, Oberschleissheim (DE)

(72) Inventor: Johannes BECKER, Ilmmünster (DE)

(73) Assignee: Schreiner Group GmbH & Co. KG, Oberschleissheim (DE)

(21) Appl. No.: 18/865,732

(22) PCT Filed: May 23, 2023
(86) PCT No.: PCT/EP2023/063789

§ 371 Date: Nov. 14, 2024

(30) Foreign Application Priority Data
May 23, 2022 (DE) 10 2022 112 902.0

(51) Int. Cl. G01R 31/68; A61J 1/03

(52) U.S. Cl. CPC G01R 31/68; A61J 1/035; A61J 2200/70

(57) ABSTRACT

An arrangement includes a first contact arrangement including a first substrate, first primary contacts and two first test contacts, wherein the first primary contacts and the first test contacts are arranged on the first substrate; a second contact arrangement including a second substrate, second primary contacts and two second test contacts, wherein the second primary contacts and the second test contacts are arranged on the second substrate; an evaluation circuit which can be and/or is electrically coupled to the first test contacts and/or the second two test contacts; wherein the first contact arrangement and the second contact arrangement are mutually arrangeable in order to couple the first and the second primary contacts electrically to one another, wherein the evaluation circuit is configured to determine a coupling state of the primary contacts depending on contacting of the first and second test contacts with one another.

### ARRANGEMENT AND METHOD

An arrangement is described, in particular an arrangement for determining an electrical coupling state of two contact arrangements, one of which is, for example, part of a medication blister. In addition, a method for determining a coupling state is described.

When placing an electronic component on connection contacts, positioning deviations may occur. These positioning deviations can, for example, lead to a malfunction and to rejects in production.

It is desirable to provide an arrangement that enables reliable determination of a coupling state. It is also desirable to provide a method that enables reliable determination of a coupling state.

According to at least one embodiment, an arrangement comprises:
a first contact arrangement, comprising a first substrate, first primary contacts and two first test contacts, wherein the first primary contacts and the first test contacts are arranged on the first substrate,
a second contact arrangement, comprising a second substrate, second primary contacts and two second test contacts, wherein the second primary contacts and the second test contacts are arranged on the second substrate,
an evaluation circuit which can be and/or is electrically coupled to the first test contacts and/or the second two test contacts,
wherein the first contact arrangement and the second contact arrangement are arrangeable on one another in order to couple the first and second primary contacts electrically to one another, wherein the evaluation circuit is configured to determine a coupling state of the primary contacts depending on contacting of the first and second test contacts to one another.

The arrangement enables a reliable determination of the coupling state of the primary contacts. For example, a coupling state in which the primary contacts are still just touching is also reliably detected, so that at least in production there is still an electrical contact between the primary contacts, but the relative positioning of the two contact arrangements is offset from one another in such a way that the electrical connection between the primary contacts can be interrupted when the arrangement is used. This risk is already detected during production in this state, since the test contacts already have no electrical contact with each other. This avoids products that are highly susceptible to failure during operation being assessed as good. There is no need to improve the positioning accuracy of the manufacturing equipment. This means that, for example, less expensive manufacturing equipment can be used. No expensive additional manufacturing equipment needs to be put into operation to ensure a high level of reliability of the arrangement. The special design of the test contacts enables a reliable determination of the coupling state of the primary contacts. The test contacts are designed and, in particular, have a shape such that, when the two arrangements are offset relative to one another, the test contacts no longer form an electrical connection, even if the primary contacts are still electrically connected to one another. The connection of the test contacts of the arrangement can be checked during production and thus specimens with an insufficient coupling state can be detected. By means of the size ratio and/or the shape of the test contacts, it is possible to specify the minimum amount of contact overlap between the primary contacts, even if the test contacts are only in minimal contact.

The evaluation circuit is therefore configured, for example, to apply an electrical current and/or an electrical voltage to the test contacts and to determine whether a closed circuit is present. The evaluation circuit is configured to check the test contacts for the presence of an electrical connection.

According to at least one further embodiment, the evaluation circuit is configured to determine the coupling state as insufficient if there is no electrical contact between one of the first test contacts and one of the second test contacts. The coupling state is determined to be sufficient if one of the first test contacts is in electrical contact with one of the second test contacts and the other of the first test contacts is in electrical contact with the other of the second test contacts. If either of these electrical contacts is interrupted, or if both of these electrical contacts are interrupted, the coupling condition is determined to be insufficient. An arrangement in which the coupling condition has been determined to be insufficient, for example during the assembly of the two contact arrangements with each other, can be sorted out. Arrangements in which the coupling state has not been determined to be inadequate are highly likely to have primary contacts that are sufficiently well positioned relative to one another, so that electrical disconnection of the primary contacts of the first arrangement from the primary contacts of the second contact arrangement can be avoided during operation.

According to at least one embodiment, the first substrate has a printed circuit board. Alternatively or additionally, the first substrate has a foil. Alternatively or additionally, the first substrate has a housing, for example a plastic housing.

The second substrate has a printed circuit board. Alternatively or additionally, the second substrate has a foil. Alternatively or additionally, the second substrate has a housing, for example a plastic housing.

For example, the foil of the first substrate and/or of the second substrate is a foil provided with conductor tracks. The primary contacts and/or the test contacts are formed on the foil. For example, the first contact arrangement has a foil as substrate. The second contact arrangement has a printed circuit board as substrate. For example, the foil is a plastic foil that is flexible.

According to at least one further embodiment, the first contact arrangement has two further first test contacts. The second contact arrangement has two further second test contacts. The evaluation circuit is configured to determine the coupling state of the primary contacts depending on contacting of the first and second test contacts with each other and of the further first and second test contacts with each other. The coupling state provides information about the positioning of the first contact arrangement and the second contact arrangement relative to one another. The eight test contacts are arranged offset to one another. The evaluation circuit is configured to determine the pair of test contacts between which no electrical connection is formed. Depending on this information, it is possible to determine how the first contact arrangement and the second contact arrangement are positioned relative to one another or arranged offset to one another. This makes it possible, for example, to readjust the production systems so that the positioning of the first contact arrangement and the second contact arrangement relative to one another is improved and all pairs of test contacts again have electrical contact in the subsequent production.

According to at least one further embodiment, the evaluation circuit is configured to determine the coupling state depending on a value of an electrical resistance between one of the first and one of the second test contacts. Thus, it is not only possible to determine whether or not contacting has occurred, but also how large the offset between the two contact arrangements is with respect to a desired positioning. For example, the greater the electrical resistance between the two test contacts, the greater the offset of the two contact arrangements relative to each other. Thus, the accuracy of the positioning of the two contact arrangements relative to each other can be determined.

According to at least one further embodiment, the first contact arrangement and the second contact arrangement can be releasably connected to one another. For example, the second contact arrangement has the evaluation circuit. The second contact arrangement with the evaluation circuit can be releasably connected to the first contact arrangement. For example, the second contact arrangement with the evaluation circuit can be subsequently connected to a further first contact arrangement. Thus, the evaluation circuit can be used with a variety of different first contact arrangements.

According to at least one further embodiment, the evaluation circuit is fixed to the second substrate. For example, the evaluation circuit is releasably fixed to the second substrate. It is also possible that the evaluation circuit is permanently connected to the second substrate. If the evaluation circuit is releasably fixed to the second substrate, it is possible to remove the evaluation circuit after determining the coupling state without having to disconnect the two contact arrangements. Thus, for example, it is possible to use the evaluation circuit to determine the coupling state of a plurality of first and second contact arrangements during manufacture.

According to at least one further embodiment, the first contact arrangement is, for example, part of a medication blister pack. Alternatively or additionally, the second contact arrangement is part of a medication blister pack. The evaluation circuit is configured to control the removal of medication from the medication blister pack. Thus, for example, it is possible to determine and/or monitor the regularity and accuracy of the removal of medication from the medication blister pack by means of the arrangement with the evaluation circuit. For example, a time of medication removal for each tablet or capsule in the blister pack can be electronically recorded and stored. Due to the precise determination of the coupling state of the primary contacts, the medication removal from the medication blister can be reliably determined during operation. Failure of the arrangement and thus incorrect determination of the medication removal can be avoided.

According to at least one embodiment, a method for determining a coupling state of a first contact arrangement and a second contact arrangement is indicated. The method is, for example, by means of an arrangement described herein according to at least one embodiment, is carried out. The features, advantages and further developments described for the arrangement thus also apply to the method and vice versa.

According to the method, the first and second contact arrangements are arranged on top of each other. A test current is applied to at least one of the first and/or at least one of the second test contacts. Contacting of the first and second test contacts with each other is determined depending on a response to the test current. A coupling state of the primary contacts is determined depending on the contacting determined.

The method thus makes it possible to reliably determine the coupling state of the primary contacts. One response to the test current, for example, is a current flowing in a closed circuit of the test contacts. If the test contacts are interrupted, there is no closed circuit and no closed circuit is detected in response to the test current. Alternatively or additionally, a test voltage can also be applied. If the test current does not flow between the first and second test contacts, the contacting is determined to be insufficient, for example. In this case, the primary contacts are not positioned precisely enough relative to one another, so that there is a certain risk that the electrical connection of the primary contacts will be disconnected during operation.

According to at least one further embodiment, a further test current is applied to further first and/or further second test contacts. The contacting of the further first and second test contacts with one another is determined depending on a response to the further test current. A positioning of the first contact arrangement and the second contact arrangement relative to one another is determined depending on the contacting determined. Thus, it is possible to precisely determine a relative offset of the two contact arrangements relative to one another.

According to at least one further embodiment, a value of an electrical resistance between the first and second test contacts is determined. The coupling state is determined depending on the value of the electrical resistance. Thus, it is possible to determine an order of magnitude of a relative offset of the two contact arrangements relative to one another. For example, the offset from a desired positioning is greater the greater the electrical resistance is.

According to at least one further embodiment, an evaluation circuit is fixed to the second substrate so that the evaluation circuit is electrically connected to the second test contacts. Subsequently, the contacting of the first and second test contacts with each other is determined and, depending on this, the coupling state is determined. In particular, the evaluation circuit is used for this purpose. In the following, the evaluation circuit is, for example, removed again from the second substrate. This makes it possible to use the evaluation circuit to determine a coupling state of a plurality of contact arrangements.

According to at least one further embodiment, a removal of medication from a medication blister pack is detected. For example, the first contact arrangement is part of a medication blister pack. Alternatively or additionally, the second contact arrangement is part of a medication blister pack. By means of the method, it is possible, as already described above in connection with the arrangement, to detect a removal of medication from the medication blister pack and, for example, to store it. The stored data relating to the removal of medication can, for example, be subsequently read out.

In the following, examples are described on the basis of schematic figures. They show:

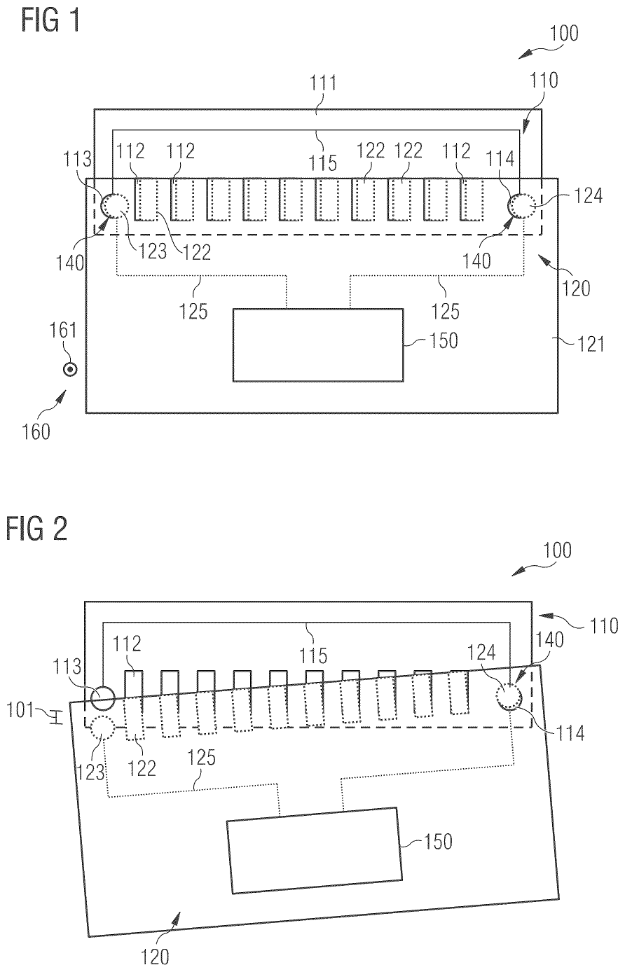

FIGS. 1 to 7 different examples of an arrangement,

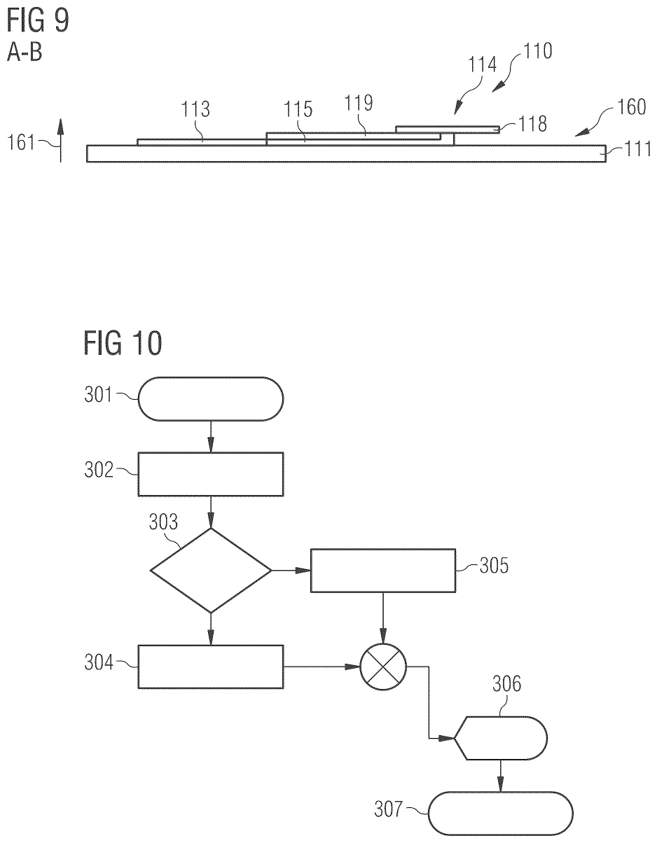

FIGS. 8 and 9 test contacts according to an example,

FIGS. 10 to 12 flowcharts for methods according to different examples,

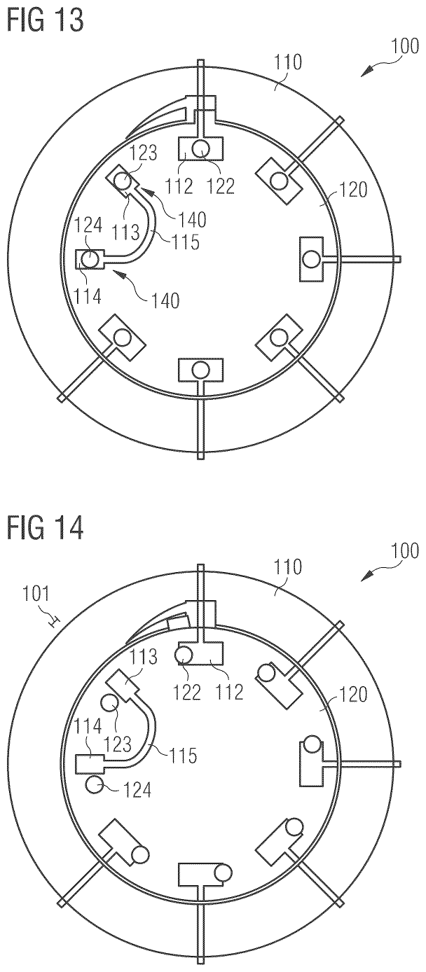

FIGS. 13 to 18 various examples of arrangements,

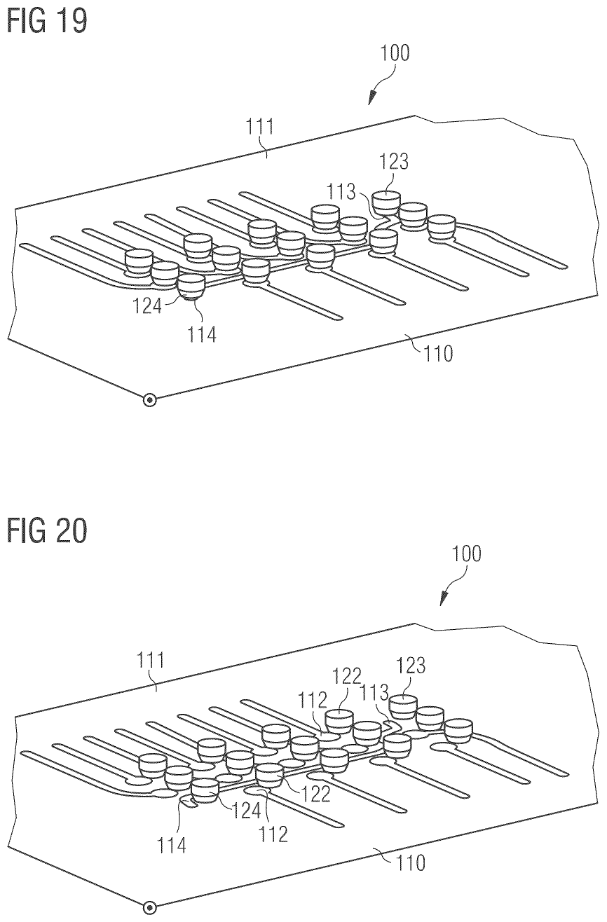

FIGS. 19 and 20 detailed views of contacts according to an example,

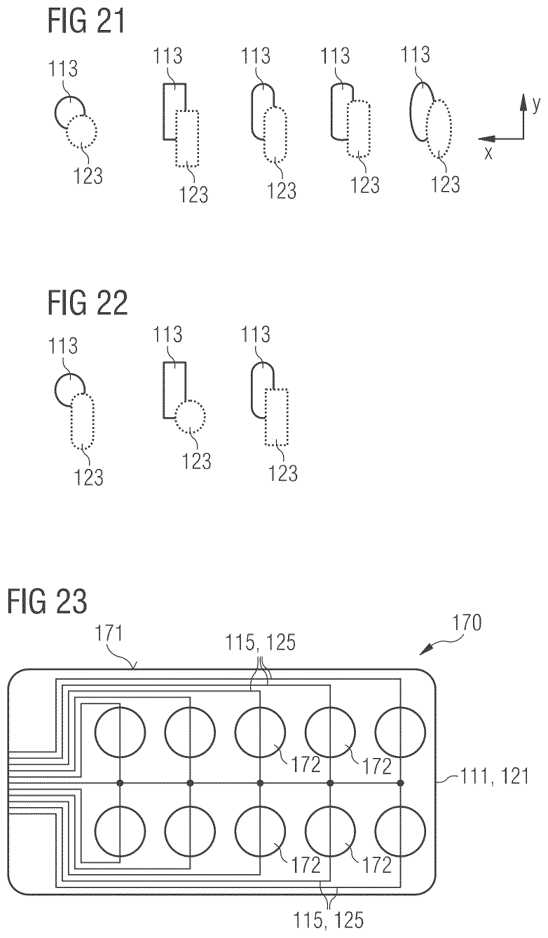

FIGS. 21 and 22 schematic representations of test contacts according to various examples,

FIG. 23 a schematic representation of a blister pack arrangement according to an example.

Elements or features of the same construction or function can be provided with the same reference signs across figures. For reasons of clarity, not all elements or features shown are marked with associated reference signs in all figures.

FIG. 1 shows an arrangement 100 according to a first example. The arrangement 100 is, for example, part of a blister pack (FIG. 23), in particular a medication blister pack. For example, the medication blister contains tablets, capsules or other dosage units of a medication. These can be removed by a patient. For example, it is possible to electronically record whether and at what time a unit of the medication was removed. Other applications are also possible in which electrical connections are configured.

During production and manufacturing, arrangement 100 can be used to determine whether two elements, for example a first substrate 111 and a second substrate 121, have been placed on top of each other with sufficient precision relative to each other. This is necessary so that primary contacts 112 and 122 are sufficiently well electrically connected to each other, for example to recognize the removal of medication.

The first primary contacts 112 are arranged on the first substrate 111. The first substrate 111 and the first primary contacts 112 are part of a first contact arrangement 110. Correspondingly, the second substrate 121 and the second primary contacts 122 are part of a second contact arrangement 120. The second primary contacts are arranged on the second substrate 121.

For example, the first contact arrangement 110 is provided to receive the medication. By means of the second contact arrangement 120, the removal of the medication can be determined and, for example, stored, and information can be subsequently read out and/or information can be stored.

The arrangement 100 has an evaluation circuit 150. The evaluation circuit 150 has, for example, at least one processor, semiconductor memory and/or further electronic components in order to execute a method and/or a computer program stored in the memory.

In the illustrated example, the evaluation circuit 150 is part of the second contact arrangement 120. It is also possible that the evaluation circuit 150 is part of the first contact arrangement 110. It is also possible that the evaluation circuit 150 is a separate element that is only temporarily connected electronically to the first contact arrangement 110 and/or the second contact arrangement 120.

The evaluation circuit 150 can be used to determine whether the first contact arrangement 110, in particular the first substrate 111 and the first primary contacts 112, is arranged with sufficient precision in a desired relative arrangement with the second contact arrangement 120, in particular with the second substrate 121 and the second primary contacts 122.

For the desired operation, the first primary contacts 121 must be sufficiently well connected to the second primary contacts 122. In particular, a sufficiently large contact area must be configured between the respective contact pairs for this purpose. FIG. 1 shows sufficiently good contacting so that the coupling state of the primary contacts 112, 122 is sufficiently good.

This state can be determined by means of the evaluation circuit 150 and test contacts 113, 114, 123, 124.

The first test contacts 113, 114 are part of the first contact arrangement 110. The first test contacts 113, 114 are arranged on the first substrate 111. The first contacts 113, 114 are electrically connected to one another by means of a connection 115. The first test contacts 113, 114 can be electrically contacted from outside the first contact arrangement 110.

The second test contacts 123, 124 are part of the second contact arrangement 120. The second test contacts 123, 124 are part of the second substrate 121. The second test contacts 123, 124 are each electrically connected to the evaluation circuit 150 by means of a connection 125. The second test contacts 123, 124 can be electrically contacted from outside the second contact arrangement 120.

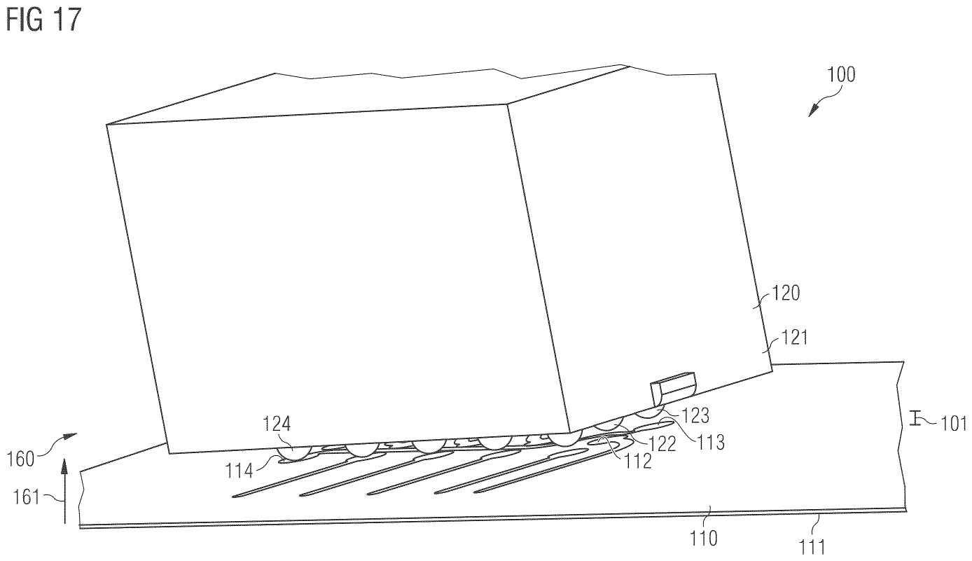

In the operation of the arrangement 100, the first contact arrangement 110 and the second contact arrangement 120 are arranged on top of each other. The first contact arrangement 110 and the second contact arrangement 120 are arranged on top of each other along a stacking direction 161 (e.g. also FIG. 17). The first contact arrangement 110 and the second contact arrangement 120 are arranged as a stack 160.

An electrical connection between the first primary contacts 112 and the associated second primary contacts 122 is to be configured by means of the arrangement on top of one another. If the arrangement is sufficiently good, the test contacts 113, 114, 123, 124 are also electrically connected to one another in pairs. In particular, the first test contact 113 is electrically connected to the associated second test contact 123. For example, a common contact surface is configured between the first test contact 113 and the second test contact 123.

Correspondingly, the first test contact 114 is electrically in contact with the second test contact 124. In particular, a common contact surface is configured between the first test contact 114 and the second test contact 124. Thus, a closed circuit is formed by means of the connections 115, 125 and the test contacts 113, 114, 123, 124. This closed circuit can be determined by means of the evaluation circuit 150.

If the electrical connection is configured at the test contact pairs 113, 123 and 114, 124, a current flow is possible and thus a sufficiently good positioning and a correspondingly sufficiently good coupling state of the primary contacts 112, 122 can be determined by means of the evaluation circuit 150. This state is shown in FIG. 1.

FIG. 2 shows the arrangement 100 in which the coupling state of the primary contacts 112, 122 is not sufficiently good, but is insufficient. The first contact arrangement 110 and the second contact arrangement 120 are arranged obliquely to one another. Thus, the first test contact 113 and the second test contact 123 are arranged at a distance 101 from each other. The two associated test contacts 113, 123 are not in contact with each other and, in particular, no electrical connection is configured. Thus, the circuit is interrupted, which can be determined by the evaluation circuit 150.

The offset, oblique or otherwise inadequate relative positioning of the two contact arrangements 110, 120 in relation to one another can be determined by means of the evaluation circuit 150 and the test contacts 113, 114, 123, 124, although electrical contacting is configured between the primary contacts 112, 122. However, the test contacts 113, 114, 123, 124 are arranged and have such an outer shape and dimensions that there is already an interruption of the electrical contact at the test contacts 113, 123, even if the primary contacts 112, 122 are electrically connected to each other. Thus, an insufficiently precise relative arrangement to one another can be precisely determined.

Incorrect positioning is not only detected when the primary contacts 112, 122 are also spaced apart and electrically disconnected from one another. Despite the electrical contact between the primary contacts 112, 122, an insufficiently precise positioning of the two contact arrangements 110, 120 relative to each other can be determined because the circuit of the connections 115, 125 and the test contacts 113, 114, 123, 124 is interrupted.

As shown in FIG. 2, it is sufficient if one of the two test contact pairs 113, 123 is spaced apart and the electrical contact at this point is interrupted. For example, an electrical contact 140 is still configured on the second test contact pair 114, 124. The insufficient coupling state is also determined by means of the evaluation circuit 150 when both test contact pairs 113, 123 and 114, 124 are separated or when the contacting 140 is configured on the test contact 113, 123 and the distance 101 is configured between the test contacts 114, 124.

The arrangement of the test contacts 113, 114, 123, 124 relative to the primary contacts 112, 122 is only to be understood as an example. The test contacts 113, 114, 123, 124 can also be arranged at any other location on the substrates 111, 121 instead of to the left and right of the primary contacts 112, 122, for example on a common side the primary contacts 112, 122 or above or below the primary contacts 112, 122. The shape of the test contacts 113, 114, 123, 124 with the round shape is also only exemplary. Other suitable shapes are also possible, as will be explained below.

The arrangement 100, by means of the evaluation circuit 150 and the test contacts 113, 114, 123, 124, enables a fault to be detected before a contact fault occurs at the primary contacts 112, 122. Thus, it is possible to determine at an early stage whether the two contact arrangements 110, 120 have been incorrectly positioned, and an error during operation can be avoided or the risk of an error occurring during use by a patient can be reduced. For example, it is still possible to read data from the first contact arrangement 110 and store it in the evaluation circuit 150 in the state shown in FIG. 2 before an error message is output. The incorrect positioning has already been detected and thus a backup storage can still take place. This would be different if the primary contacts 112, 122 are already separated and an error is only then detected. Then it would no longer be possible to read data from the first contact arrangement 110 using the second contact arrangement 120.

When the two contact arrangements 110, 120 are automatically assembled on top of each other, it is possible to detect insufficiently precise positioning and contacting independently of the primary contacts 112, 122. In the case of a positioning as shown in FIG. 2, no error would be detected during automatic assembly without the test contacts. However, due to the oblique positioning relative to each other, there is a high probability that the electrical contact between the primary contacts 112, 122 will be interrupted during operation. The inclined positioning is already detected during production by means of the test contacts 113, 114, 123, 124 and the arrangement 100 with the positioning as shown in FIG. 2 can already be sorted out before it is issued to a user.

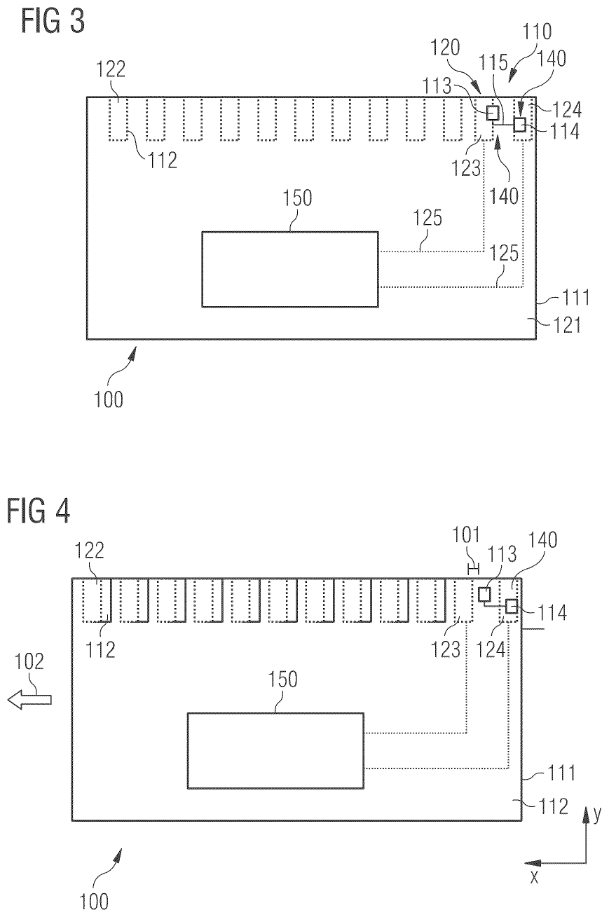

FIGS. 3 to 7 show further examples of the arrangement 100 and in particular of the test contacts 113, 114, 123, 124.

As shown in FIG. 3, the test contacts 113, 114 can be configured to be significantly smaller than the second test contacts 123, 124. The test contacts 113, 114, 123, 124, for example, have a rectangular shape. The contact pairs 113, 123 and 114, 124 are arranged on a common side next to the primary contacts 112, 122.

In FIG. 3, the positioning of the contact arrangements 110, 120 is as desired and the coupling state of the primary contacts 112, 122 is sufficiently good. The electrical contact 140 is configured both on the test contact pair 113, 123 and on the test contact pair 114, 124. This can be detected by means of the evaluation circuit 150 and thus the coupling state can be determined as sufficiently good.

FIG. 4 shows the arrangement 100 of FIG. 3 with insufficient positioning and an insufficient coupling state. For example, the first contact arrangement 110 has an offset 102 along a first direction X relative to the second contact arrangement 120. The primary contacts 112, 122 are still electrically connected to one another, but the overlap area is so small that there is a risk of interruption during operation. This can be determined at an early stage because there is already a distance 101 between the first test contact 113 and the second test contact 123 due to the offset 102. The test contacts 113, 123 are dimensioned and arranged in such a way that, with the offset 102 along the X-direction, the distance 101 occurs as soon as the overlap area of the primary contacts 112, 122 falls below a predetermined minimum size. For example, the distance between the first test contacts 113, 114 along the X-direction is so small compared to the distance between the second test contacts 123, 124 that the distance 101 already occurs at the offset 102.

FIG. 5 shows the arrangement 100 according to FIG. 3 with an offset 103 along a Y-direction. The distance 101 is configured along the Y-direction at the test contact pair 114, 124. The test contact pair 113, 123 still has an electrical contact 140. However, the circuit is interrupted at the test contact pair 114, 124. The dimensions, in particular of the first test contacts 113, 114, are configured such that, if a desired minimum contacting area between the primary contact 112, 122 is undershot, the distance 101 occurs at least at one of the test contact pairs 113, 123 and 114, 124.

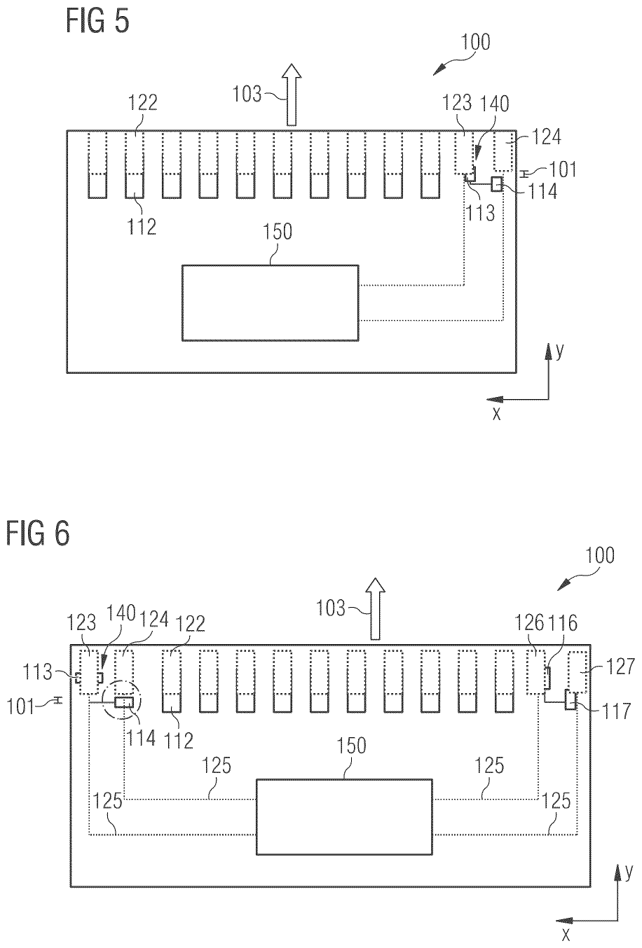

FIG. 6 shows the arrangement 100 according to a further example. In contrast to the examples according to FIGS. 1 to 5, the arrangement 100 according to FIG. 6 has four test contact pairs.

In addition to the first test contacts 113, 114, the first contact arrangement 110 has further first test contacts 116, 117. In addition to the second test contacts 123, 124, the second contact arrangement 120 has further second test contacts 126, 127.

The respective contact pairs 113 and 123, 114 and 124, 116 and 126, 117 and 127 are arranged in such a way that, by means of the evaluation circuit 150 can determine the position of the electrical interruption and thus determine the direction in which a relative displacement or the offset 103 or the offset 102 (FIG. 4) occurs.

In the illustrated example, the distance 101 is configured between the test contacts 114 and 124. Since a closed circuit is present at the further test contacts 116, 117, 126, 127, the evaluation circuit 150 is able to determine that there is an offset along the Y-direction. If the circuit is interrupted at the other test contacts 116, 117, 126, 127, an offset along the X-direction can be determined. In the illustrated example, this is realized by the first test contacts 113, 114 being longer along the X-direction than along the Y-direction. The other first test contacts 116, 117 are longer along the Y-direction than along the X-direction.

Instead of the different extensions and shapes of the test contacts, it is also possible, for example, to realize the interruption or the distance 101 at different test contact pairs by positioning the test contacts 113, 114, 116, 117 and 123, 124, 126, 127 on substrates 111 and 121, respectively, to realize the interruption or the distance 101 at different test contact pairs depending on the direction in which the offset 102 or the offset 103 occurs.

An offset in the X-direction and an offset in the Y-direction can be recognized separately from each other. The first and second test contacts 113, 114, 123, 124 are monitored separately from the further test contacts 116, 117, 126, 127 by the evaluation circuit 150.

It is also possible to connect all contact pairs 113 and 123, 114 and 124, 116 and 126, 117 and 127 electrically in series and to monitor them with one input of the evaluation circuit 150.

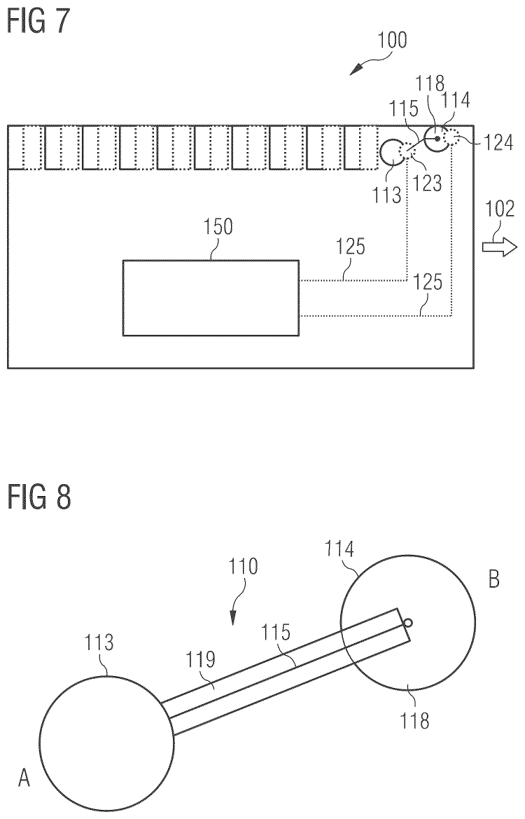

FIGS. 7 to 9 show the arrangement 100 according to an example in which the extent of the offset 102 or 103 can be determined.

For example, the test contact 114 has a high-resistance element 118. Along the stacking direction 161 (FIG. 9), the high-resistance element 118 is arranged above the connection 115 to the test contact 113. The connection 115 is electrically insulated from the high-resistance element 118 by means of an insulation 119. In the center, the high-resistance element 118 is configured with an electrical connection to the connection 115. If the second contact arrangement 120 is arranged at the desired location relative to the contact arrangement 110, the test contact 124 is arranged in the center of the test contact 114 and on the high-resistance element 118. Thus, a comparatively low electrical resistance is configured overall, since the current only has to flow a short distance through the high-resistance element 118 to the connection 115.

If there is an offset, as for example shown in FIG. 7, the test contact 124 of the second contact 120 is out of center and in contact with the high-resistance element 118. Since the current has to flow a comparatively greater distance through the high-resistance element 118, there is greater overall electrical resistance.

The different electrical resistances can be determined and evaluated by the evaluation circuit 150. Thus, it is not only possible to recognize whether there is an offset 102, 103 at all, but also how large this offset 102, 103 is. The greater the electrical resistance in the circuit with the first test contacts 113, 114, the second test contacts 123, 124 and the connections 115 and 125, the greater the offset 102 or 103.

It is also possible to combine the various examples. For example, in accordance with an example not explicitly represented, the arrangement 100 has four pairs of contacts, as shown in FIG. 6, wherein the test contacts are configured at least in part as shown in connection with FIGS. 7 to 9 and have high-resistance elements 118. Thus, the direction of the offset and the magnitude of the offset 102, 103 can be determined. In addition, it is possible, for example, to use a rectangular shape or another shape for the test contacts instead of a round shape in the example of FIGS. 7 to 9.

The example of FIGS. 7 to 9 allows for an analog evaluation to determine the amount of offset 102, 103. If the offset 102, 103 is in the correct position, in which the test contacts 114, 124 and 113, 123 are centered in relation to each other, the electrical resistance of the connection from the evaluation circuit 150 via the test contacts 113, 114, 123, 124 increases.

The coupling state is determined to be inadequate, for example, if the electrical resistance exceeds a predetermined threshold value. For this purpose, the first test contact 113 has a low electrical resistance and the first test contact 114 has the high-resistance element 118 and thus a high electrical resistance. The connection 115 has a low electrical resistance.

FIG. 10 shows a flow chart of a method according to an example for determining the coupling state.

In step 301, the verification of the relative positioning is started.

In step 302, the contacting of the test contact pairs 113, 123 and 114, 124 is determined.

In a step 303, it is determined whether both test contact pairs 113, 123 and 114, 124 are electrically connected.

If a positive result is determined in step 303, a step 304 determines that the positioning of the two contact arrangements 110, 120 relative to each other is as intended.

If a negative result is determined in step 303, a step 305 is used to determine that the relative positioning of the two contact arrangements 110, 120 relative to one another is not as intended.

The result of the determination is then output in a step 306.

The method is then terminated in a step 307.

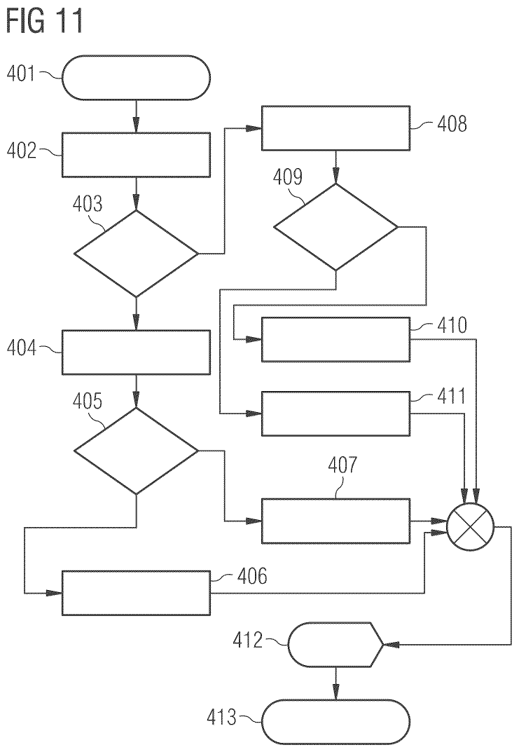

FIG. 11 shows a flowchart of the method for determining the coupling state according to a further example. For example, the method according to FIG. 11 is carried out on the arrangement 100 having four test contact pairs.

In step 401, the method is started.

In a step 402, contacting at the test contact pairs 113, 123 and 114, 124 is determined.

In step 403, it is determined whether test contact pairs 113, 123 and 114, 124 are electrically connected to each other. If the result is negative, the process continues with step 408. If the result is positive, the process continues with step 404.

In step 404, the contacting of the test contact pairs 116, 126 and 117, 127 is determined.

In step 405, it is determined whether test contact pairs 116, 126 and 117, 127 are electrically connected to one another. If the result is positive, the process continues with step 406. If the result is negative, the process continues with step 407.

In step 406, it is determined that the relative positioning of the two contact arrangements 110 and 120 is as intended.

In step 407, it is determined that the positioning along one of the directions X and Y, for example along the direction X, is not correct.

In step 408, the contacting of the contact pairs 116, 126 and 117, 127 is determined.

In a step 409, it is determined whether there is electrical contact at the test contact pairs 116, 126 and 117, 127. If the result is positive, the process continues with step 411. If the result is negative, the process continues with a step 410.

In step 410, it is determined that the positioning along both the X and Y directions is not as intended.

In step 411, it is determined that the positioning along one of the X and Y directions is not as intended, for example along the Y direction.

In step 412, the result is output.

In a step 413, the method is ended.

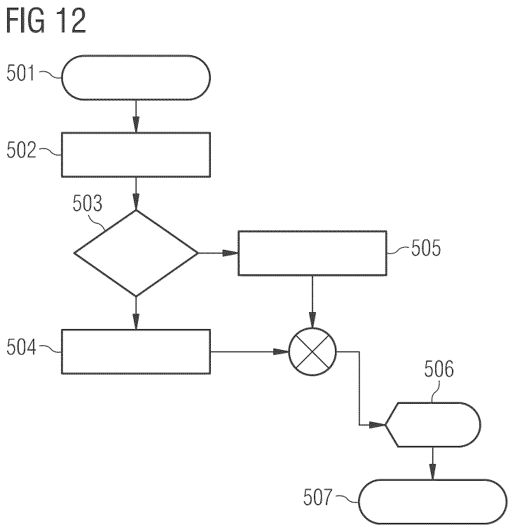

FIG. 12 shows a flow chart for the method for determining the contact state according to a further example, in which an analog evaluation is realized.

In a step 501, the determination is started.

In a step 502, the resistance at the test contacts 113, 114, 123, 124 is measured or determined.

In step 503, it is determined whether the electrical resistance determined is less than or equal to the specified threshold or limit value. If the result is positive, the process continues with step 504. If the result is negative, the process continues with step 505.

In step 504, it is determined that the relative positioning of the two contact arrangements 110, 120 is correct.

In step 505, it is determined that the relative positioning of the two contact arrangements 110, 120 is not as desired.

In step 506, the result is output.

In a step 507, the method is ended.

FIGS. 13 and 14 show the arrangement 100 according to a further example. The first contact arrangement 110 and the second contact arrangement 120 are coupled to one another, for example, by rotating.

FIG. 13 shows the two contact arrangements 110, 120 correctly positioned in relation to one another.

FIG. 14 shows inadequate positioning, in which the second contact arrangement 120, for example, has not been screwed far enough into the first contact arrangement 110. Thus, the distance 101 is configured between the test contacts 113, 123.

In the example of FIGS. 13 and 14, the first two test contacts 113, 114 are arranged next to each other. The first two test contacts 113, 114 are connected to each other by means of a bent connection 115.

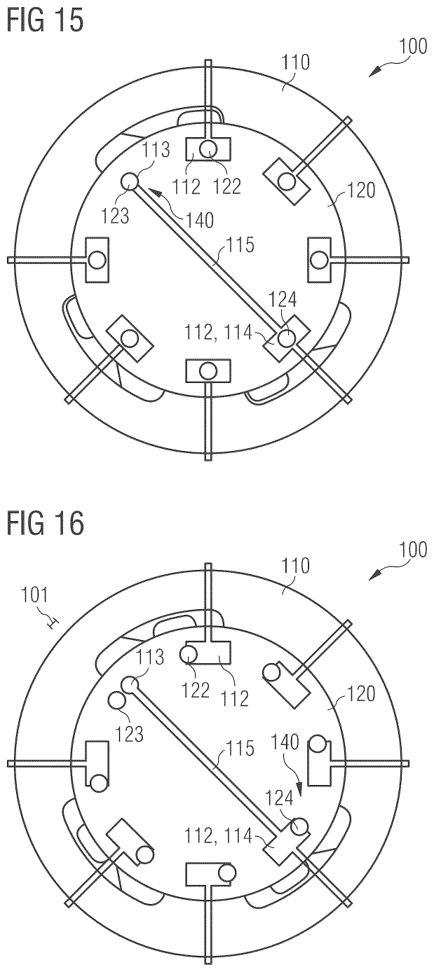

FIGS. 15 and 16 show a further example of the arrangement 100, in which the first test contacts 113, 114 are arranged radially opposite one another. The two first test contacts 113, 114 are electrically connected to one another by means of a straight connection 115. For example, the first test contacts 113, 114 have different shapes from one another. For example, the first test contact 114 also serves as the primary contact 112. Thus, even if the relative positioning is insufficient, the electrical contact 114 is configured on the second test contact 124. However, the distance 101 is configured between the test contact pair 113, 123. For example, test contact 113 is configured to be smaller than test contact 114 and/or the associated primary contact 112 connected by means of connection 115.

The examples shown in FIGS. 13 to 16 each show an arrangement in which the first contact arrangement 110 is configured as a medication blister and/or the first substrate 111 is configured as a foil. The second contact arrangement 120 is configured, for example, as a reusable and removable element that can be arranged with a plurality of different first contact arrangements 110. For example, when all the medication has been taken from the first contact arrangement 110, the second contact arrangement 120 is removed again and coupled to a further first contact arrangement 110 that contains new medication. For coupling and releasing again, the second contact arrangement 120 is screwed in, for example. In these examples, the second contact arrangement 120 has the evaluation circuit 150, which is, for example, firmly connected to the second substrate 121.

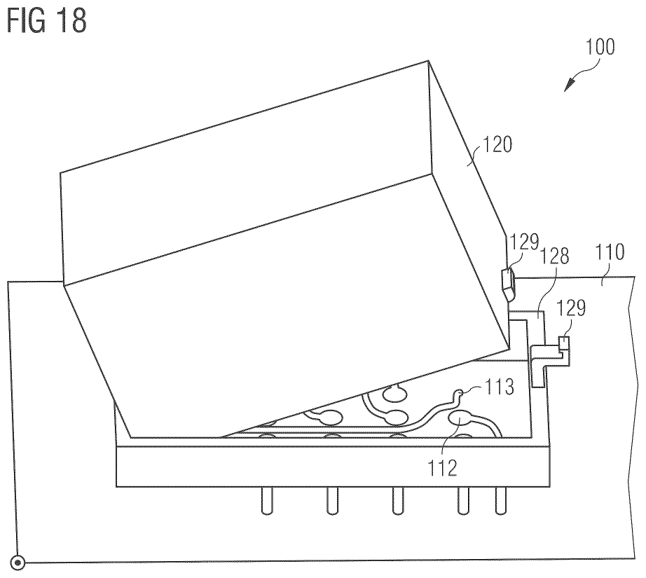

FIGS. 17 and 18 show an example of the arrangement 100, in which the reusable contact arrangement 120 is coupled to the first contact arrangement 110 by means of pivoting. A mounting frame 128 is configured on the first substrate 111. The second contact arrangement 120, for example a housing containing the second substrate 121 and further elements, such as the evaluation circuit 150, is swung into the mounting frame 128 and mechanically fastened by means of a snap fit 129.

The mounting frame 128 surrounds, for example, the first primary contacts 112 and the first test contacts 113, 114.

If it is not swung in sufficiently, the distance 101 between the test contact pair 113, 123, for example, is configured as shown in FIG. 17. For example, if there is dirt between the two contact arrangements 110, 120, the snap fit 119 is engaged, but no electrical contact is formed between the test contact pairs 113, 123. This can be determined by means of the evaluation circuit 150, even if the primary contacts 112, 122 are initially connected to one another. The risk that the contamination also interrupts the connection of the primary contacts 112, 122, for example, can thus be determined at an early stage.

FIGS. 19 and 20 show the arrangement 100 according to a further example, in which the first contact arrangement 110 and the second contact arrangement 120 are coupled to one another by means of horizontal sliding. The first substrate 111 is, for example, a foil and the second contact arrangement 120 is a reusable evaluation device with the evaluation circuit 150. In FIG. 19, the two contact arrangements 110, 120 is realized so that the test contacts 113, 123, 114, 124 are each electrically connected to the evaluation circuit 150 and a continuous circuit is closed.

In FIG. 20, the second contact arrangement 120 is not correctly engaged and the relative positioning between the two contact arrangements 110 and 120 is not sufficiently good.

The circuit is not closed, which can be determined by the evaluation circuit 150.

FIG. 21 shows examples of various external shapes and designs for test contacts 113, 123, wherein the external shape of the two test contacts 113, 123 is the same in each case. The examples in FIG. 21 can also be applied to the other test contacts 114, 116, 117, 124, 126, 127.

As shown in FIG. 21, the outer shapes of the respective test contacts 113, 123 are the same in each case, wherein a round shape, an oval shape, a rectangular shape and mixed shapes are possible. It is possible that the test contacts are equally extended in both spatial directions X, Y or that they are longer in one of the two directions, for example along the Y-direction, than along the other direction.

FIG. 22 shows examples of the outer shape of test contacts 113, 123, wherein the outer shape of the first test contact 113 differs from the outer shape of the second test contact 123. The design examples of FIG. 22 can be applied to the other test contacts 114, 116, 117, 124, 126, 127. A wide variety of combinations of the outer shape are possible, for example test contacts 113, 123 of different sizes. Rectangular test contacts 113, 123 can be combined with round or oval test contacts 123, 113. Likewise, the various mixed forms can be combined with each other.

It is also possible that some of the test contact pairs 113 and 123, 114 and 124, 116 and 126, 117 and 127 have the same external shape and another part of the test contact pairs 113 and 123, 114 and 124, 116 and 126, 117 and 127 has an outer shape that differs from one another.

FIG. 23 shows a schematic representation of an exemplary medicament package, such as a blister pack 170 or a foldable medicament sleeve. The blister pack 170 is electronically readable. Within the surface extent of the blister arrangement 170, which is surrounded by its outer edge 171, the lateral positions of cavities 172, i.e. the bulges of the blister film for inserting the tablets, for example, as well as exemplary conductor paths of the connections 115, 125, which are assigned to these cavities 172, are shown. The connections 115, 125 are configured as conductor tracks, for example. FIG. 23 is not to be understood as a top view or sectional view of the blister film or the closure film, of which the blister pack 170 predominantly consists, but this figure is merely intended to show—irrespective of the layer structure of the blister pack 170 that can be selected in each case—an exemplary planar arrangement of cavities and conductor tracks or conductor track courses; furthermore, they naturally apply irrespective of the specific outline shape of the cavities, which can also be oval or otherwise rounded and/or elongated (instead of circular). In FIG. 23, it can be seen that in blister pack 170, the conductor tracks 115, 125 associated with cavities 172 have contactable conductor track ends. For example, the conductor track ends can be contacted by means of the evaluation circuit 150. For example, the conductor tracks or a part of the conductor tracks are connected to the evaluation circuit 150 in order to electrically control and evaluate the conductor tracks 115, 125 of the blister pack 170, which is done, for example, periodically or continuously over time.

The arrangement 100 according to the various examples enables the detection of insufficiently good positioning of the two contact arrangements 110, 120 relative to one another. Thus, for example, in automated production, a better determination of insufficiently well-assembled arrangements is achievable, so that these can already be sorted out during production. If possible, no arrangements 100 with an insufficient coupling state of the primary contacts are delivered. The tolerance is selected according to the examples in such a way that it moves in the wrong negative direction, i.e. for example, an insufficient coupling state is determined in a good borderline case. Thus, a correct positive is achieved with a good connection of the primary contacts and a good connection of the test contacts, while if the test contacts are open, an insufficient coupling state is determined if possible.

Even in the case of reusable arrangements 100 that are coupled together by users, insufficiently good couplings between the first contact arrangement 110 and the second contact arrangement 120 can be determined, so that it can be ensured as far as possible that the user only operates the arrangement 110 if the contact arrangements 110, 120 are connected sufficiently well. Otherwise, it is possible, for example, to issue an error message to the user.

The determination is made in particular by the electronics, which check the test contacts 113, 114, 123, 124 for the presence of the electrical connection. Thus, the reliability of the arrangement 100, for example when determining the removal of medication, is increased overall.
Reference signs
100 arrangement
101 distance
102, 103 offset
110 first contact arrangement
111 first substrate
112 first primary contacts
113, 114 first test contacts
115 connection
116, 117 further first test contacts
118 high-resistance element
119 insulation
120 second contact arrangement
121 second substrate
122 second primary contacts
123, 124 second test contacts
125 connection
126, 127 further second test contacts
128 mounting frame
129 snap fit
140 electrical contacting
150 evaluation circuit
160 stack
161 stacking direction
170 blister pack
171 outer edge
172 cavity
301-307 method steps
401-413 method steps
501-507 method steps

1. An arrangement comprising:
a first contact arrangement (110) comprising a first substrate (111), first primary contacts (112), and two first test contacts (113, 114), wherein the first primary contacts (112) and the first test contacts (113, 114) are arranged on the first substrate (111),
a second contact arrangement (120) comprising a second substrate (121), second primary contacts (122) and two second test contacts (123, 124), wherein the second primary contacts (122) and the second test contacts (123, 124) are arranged on the second substrate (121),
an evaluation circuit (150) that can be and/or is electrically coupled to the first test contacts (113, 114) and/or the second two test contacts (123, 124),
wherein the first contact arrangement (110) and the second contact arrangement (120) are arrangeable on one another in order to couple the first and the second primary contacts (113, 114, 123, 124) electrically to one another, wherein the evaluation circuit (150) is configured to determine a coupling state of the primary contacts (112, 122) depending on a contact between the first and second test contacts (113, 114, 123, 124).

2. The arrangement according to claim 1, wherein the evaluation circuit (150) is configured to determine the coupling state as insufficient if no electrical contact is formed between one of the first and one of the second test contacts (113, 114, 123, 124).

3. The arrangement according to claim 1, in which the first substrate (111) comprises a printed circuit board and/or a foil and/or a housing and the second substrate (121) comprises a printed circuit board and/or a foil and/or a housing.

4. The arrangement according to claim 1, wherein the first contact arrangement (110) has two further first test contacts (116, 117) and the second contact arrangement (120) has two further second test contacts (126, 127), wherein the evaluation circuit (150) is configured to determine the coupling state of the primary contacts (113, 114, 123, 124) depending on contacting of the first and second test contacts (113, 114, 123, 124) with one another and the further first and second test contacts (116, 117, 126, 127) ) to determine the coupling state of the primary contacts (113, 114, 123, 124), wherein the coupling state comprises information about the positioning of the first contact arrangement (110) and the second contact arrangement (120) relative to one another.

5. The arrangement according to claim 1, wherein the evaluation circuit (150) is configured to determine the coupling state depending on a value of an electrical resistance between the first and the second test contacts (113, 114, 123, 124).

6. The arrangement according to claim 1, wherein the first contact arrangement (110) and the second contact arrangement (120) are releasably connectable to one another.

7. The arrangement according to claim 1, wherein the evaluation circuit (150) is fixed to the second substrate (121), in particular releasably fixed.

8. The arrangement according to claim 1, in which the evaluation circuit (150) is configured to determine that the contacting is insufficient if at least one of the first test contacts (113, 114) is arranged at a distance from the corresponding second test contact (123, 124).

9. The arrangement according to claim 1, wherein the first contact arrangement (110) and/or the second contact arrangement (120) is part of a medication blister and the evaluation circuit (150) is configured to control the removal of medication from the medication blister.

10. A method for determining a coupling state of a first contact arrangement (110) and a second contact arrangement (120), wherein the first contact arrangement (110) has a first substrate (111), first primary contacts (112) and two first test contacts (113, 114), wherein the first primary contacts (112) and the first test contacts (113, 114) are arranged on the first substrate (111), and wherein the second contact arrangement (120) has a second substrate (121), second primary contacts (122) and two second test contacts (123, 124), wherein the second primary contacts (122) and the second test contacts (123, 124) are arranged on the second substrate (121), the method comprising:
arranging the first and second contact arrangements (110, 120) on top of each other,
applying a test electrical current to at least one of the first and/or at least one of the second test contacts (113, 114, 123, 124),
detecting a contacting of the first and second test contacts (113, 114, 123, 124) with each other depending on a response to the test current,
determining the coupling state of the primary contacts depending on the contacting determined.

11. The method according to claim 10, comprising:
determining the contacting as insufficient if the test current does not flow between one first and one second test contact (113, 114, 123, 124).

12. The method according to claim 10, wherein the first contact arrangement (110) comprises two further first test contacts (116, 117) and the second contact arrangement (120) comprises two further second test contacts (126, 127), the method comprising:
applying a further test current to the further first and/or the further second test contacts (116, 117, 126, 127),
determining the contacting of the further first and second test contacts (116, 117, 126,

127) with one another depending on a response to the further test current,
determining a positioning of the first contact arrangement (110) and the second contact arrangement (120) relative to one another depending on the contacting determined.

13. The method according to claim 10, comprising:
determining a value of an electrical resistance between the first and second test contacts (113, 114, 123, 124),
determining the coupling state depending on the value of the electrical resistance.

14. The method according to claim 10, comprising:
fixing an evaluation circuit (150) to the second substrate (121) so that the evaluation circuit (150) is electrically connected to the second test contacts (123, 124),
removing the evaluation circuit (150) from the second substrate (121) after the coupling state has been determined.

15. The method according to any one of claims 10 to claim 10, wherein the first contact arrangement (110) and/or the second contact arrangement (120) is part of a medication blister, the method comprising:
detecting a medication removal from the medication blister.
